(19) United States
(12) Patent Application Publication
(10) Pub. No.: US 2016/0282212 A1
(43) Pub. Date: Sep. 29, 2016

(54) MOLDED SEMICONDUCTOR PACKAGE HAVING ENHANCED LOCAL ADHESION CHARACTERISTICS

(71) Applicant: Infineon Technologies AG, Neubiberg (DE)

(72) Inventors: Sebastian Beer, Regensburg (DE); Helmut Wietschorke, Laberweinting (DE); Jochen Dangelmaier, Beratzhausen (DE); Horst Theuss, Wenzenbach (DE); Bernhard Knott, Neumarkt (DE); Thomas Mueller, Lappersdorf (DE); Andreas Allmeier, Pfatter (DE)

(21) Appl. No.: 14/667,858

(22) Filed: Mar. 25, 2015

(51) Int. Cl. G01L 19/14; H01L 25/18; H01L 21/52; H01L 21/56; H01L 23/31; H01L 23/495

(52) U.S. Cl. CPC G01L 19/147; H01L 23/3142; H01L 23/49558; H01L 21/52; H01L 21/565; H01L 25/18; H01L 23/49575

(57) ABSTRACT

A molded semiconductor package includes a substrate having opposing first and second main surfaces, a semiconductor die attached to the first main surface of the substrate, an adhesion adapter attached to the second main surface of the substrate or a surface of the semiconductor die facing away from the substrate, and a mold compound encapsulating the semiconductor die, the adhesion adapter and at least part of the substrate. The adhesion adapter is configured to adapt adhesion properties of the mold compound to adhesion properties of the substrate or semiconductor die to which the adhesion adapter is attached, such that the mold compound more strongly adheres to the adhesion adapter than directly to the substrate or semiconductor die to which the adhesion adapter is attached. The adhesion adapter has a surface feature which strengthens the adhesion between the adhesion adapter and the mold compound.

### TECHNICAL FIELD

The instant application relates to molded semiconductor packages, and more particularly to molded semiconductor packages with enhanced local adhesion characteristics.

### BACKGROUND

Molded semiconductor packages include one or more semiconductor dies (chips) attached to a substrate and encapsulated by a mold compound. Delamination between the mold compound and a die and/or between the mold compound and the substrate allows humidity and contaminants to penetrate the package. Delamination is a particularly pressing concern for molded semiconductor packages such as sensor packages that have an open passage for permitting some form of coupling with air. For example, a pressure sensor transducer converts pressure of the air entering the passage into an electrical signal for analysis. The molding compound is much more likely to delaminate from the substrate along the interface with the open passage. To prevent delamination and humidity and contaminants from penetrating the package, adhesion between the mold compound and the package substrate should be increased, especially along the interface with any open passages. Adhesion is the tendency of dissimilar particles or surfaces to cling to one another. Adhesion is typically increased in molded semiconductor packages by pre-treating the substrate e.g. with an adhesion promoter or by surface roughening, or by adding substances to the mold compound which increase adhesion. Such approaches increase cost and may not sufficiently reduce the delamination risk over the entire operating widow (pressure, temperature) for which the package is rated.

### SUMMARY

According to an embodiment of a molded semiconductor package, the molded semiconductor package comprises a substrate having opposing first and second main surfaces, a semiconductor die attached to the first main surface of the substrate, an adhesion adapter attached to the second main surface of the substrate or a surface of the semiconductor die facing away from the substrate, and a mold compound encapsulating the semiconductor die, the adhesion adapter and at least part of the substrate. The adhesion adapter is configured to adapt adhesion properties of the mold compound to adhesion properties of the substrate or semiconductor die to which the adhesion adapter is attached, such that the mold compound more strongly adheres to the adhesion adapter than directly to the substrate or semiconductor die to which the adhesion adapter is attached. The adhesion adapter also has a surface feature which strengthens the adhesion between the adhesion adapter and the mold compound.

According to another embodiment of a molded semiconductor package, the molded semiconductor package comprises a substrate having opposing first and second main surfaces, a pressure sensor comprising a first side with a pressure sensor port facing the first main surface of the substrate, a second side opposite the first side, and electrical contacts, and a logic die stacked on the pressure sensor and comprising a first side attached to the second side of the pressure sensor and a second side opposite the first side with electrical contacts. The logic die is laterally offset from the electrical contacts of the pressure sensor and operable to process signals from the pressure sensor. The molded semiconductor package further comprises an adhesion adapter attached to the second main surface of the substrate and a mold compound encapsulating the pressure sensor, the logic die and the adhesion adapter, the mold compound having an opening defining an open passage to the pressure sensor port. The adhesion adapter is configured to adapt adhesion properties of the mold compound to adhesion properties of the substrate such that the mold compound more strongly adheres to the adhesion adapter than directly to the substrate. The adhesion adapter has a surface feature which strengthens the adhesion between the adhesion adapter and the mold compound.

According to an embodiment of a method of manufacturing a molded semiconductor package, the method comprises: providing a substrate having opposing first and second main surfaces; attaching a semiconductor die to the first main surface of the substrate; attaching an adhesion adapter to the second main surface of the substrate or a surface of the semiconductor die facing away from the substrate; encapsulating the semiconductor die, the adhesion adapter and at least part of the substrate in a mold compound, wherein the adhesion adapter is configured to adapt adhesion properties of the mold compound to adhesion properties of the substrate or semiconductor die to which the adhesion adapter is attached, such that the mold compound more strongly adheres to the adhesion adapter than directly to the substrate or semiconductor die to which the adhesion adapter is attached; and providing the adhesion adapter with a surface feature which strengthens the adhesion between the adhesion adapter and the mold compound.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional view of an embodiment of a molded semiconductor package having an adhesion adapter.

FIG. 2 illustrates a cross-sectional view of another embodiment of a molded semiconductor package having an adhesion adapter.

FIG. 3 illustrates a cross-sectional view of yet another embodiment of a molded semiconductor package having an adhesion adapter.

FIG. 4 illustrates a cross-sectional view of still another embodiment of a molded semiconductor package having an adhesion adapter.

FIG. 5 illustrates a cross-sectional view of another embodiment of a molded semiconductor package having an adhesion adapter.

FIGS. 6 through 8 illustrate different surface feature embodiments for the adhesion adapter.

FIG. 9 illustrates a cross-sectional view of an embodiment of a molded pressure sensor package having an adhesion adapter.

FIG. 10 illustrates an embodiment of a method of attaching the adhesion adapter to a substrate of a molded semiconductor package.

### DETAILED DESCRIPTION

According to embodiments described herein, adhesion to the molding compound of a molded semiconductor package is locally increased using an adhesion adapter attached to the substrate or semiconductor die of the package. The adhesion adapter can comprise the same or different material as the substrate, but is not an integral, continuous part of the substrate or die. Instead, the adhesion adapter is a discrete (additional) component attached to the substrate or die. The package can include more than one adhesion adapter e.g. one adhesion adapter can be attached to the bottom surface of the substrate and an additional adhesion adapter can be attached to the side of the die facing away from the substrate. In each case, the adhesion adapter is configured to adapt the adhesion properties of the mold compound to the adhesion properties of the package component to which that adhesion adapter is attached, such that the mold compound more strongly adheres to the adhesion adapter than directly to the component to which the adhesion adapter is attached.

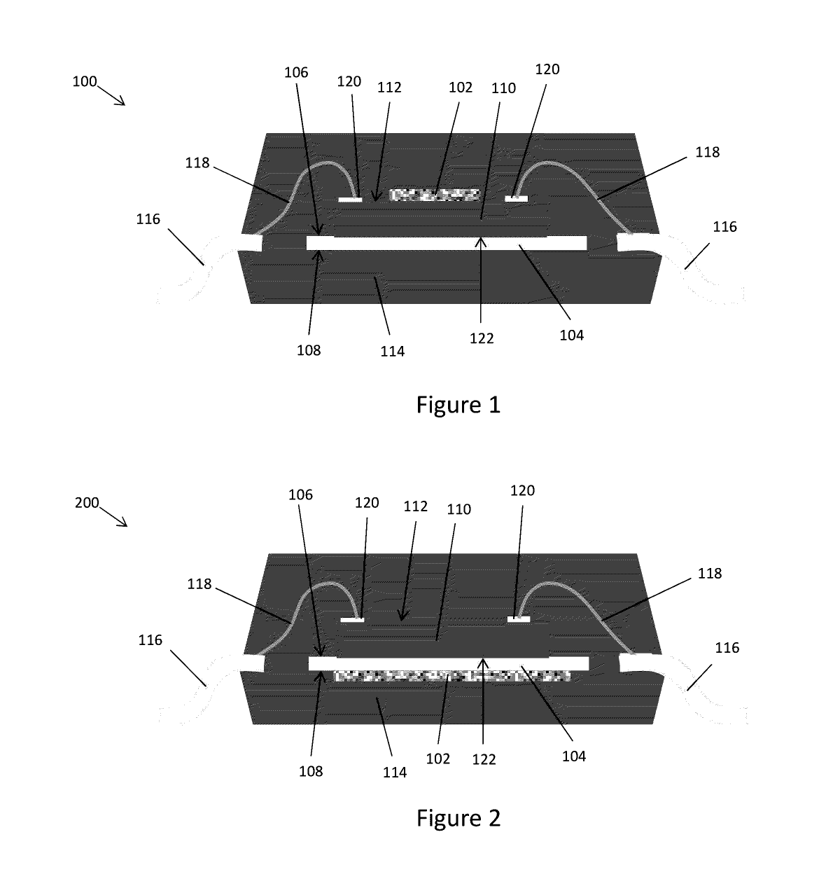

FIG. 1 illustrates a sectional view of an embodiment of a molded semiconductor package 100 having an adhesion adapter 102. The molded semiconductor package 100 also includes a substrate 104 having opposing first and second main surfaces 106, 108 and a semiconductor die 110 attached to the first main surface 106 of the substrate 104. Any type of substrate 104 and semiconductor die 110 die can be used. For example, the semiconductor die 110 can be an active semiconductor die such as a power transistor or diode die, logic die, sensor die, processor die, etc., or a passive die such as a capacitor die. The substrate 104 can be a circuit board such as a PCB (printed circuit board), flex board, etc., a foil, ceramic, a metal base plate, a lead frame, etc. More than one die 110 can be attached to the substrate 104, and more than one substrate 104 can be included in the molded semiconductor package 100.

According to the embodiment illustrated in FIG. 1, the adhesion adapter 102 is attached to the surface 112 of the semiconductor die 110 facing away from the substrate 104. The die 110 and adhesion adapter 102 can comprise the same or different materials, and can be electrically insulating or conductive. As such, the process for attaching the adhesion adapter 102 to the semiconductor die 110 can vary widely depending on package type. For example, the adhesion adapter 102 can be attached to the semiconductor die 110 by gluing, welding, brazing, soldering, bolting, riveting, etc. The adhesion adapter 102 can be made of metal, plastic, Si, glass, etc. and can comprises a single layer of material or multiple layers of the same or different materials. The geometry of the adhesion adapter 102 can vary depending on the composition and placement of the adhesion adapter 102. For example, the adhesion adapter 102 can be flat, e.g. a stamped part. In each case, the adhesion adapter 102 is a discrete component attached to the substrate 104 or die 110. That is, the adhesion adapter 102 is not an integral, continuous part of the substrate 104 or die 110, but instead is an additional part/component of the molded semiconductor package 100.

The molded semiconductor package 100 also includes a mold compound 114 such as silicone, epoxy, etc. which encapsulates the semiconductor die 110, the adhesion adapter 102 and at least part of the substrate 104. Leads 116, which can protrude from the mold compound 114, provide external points of electrical contact for the package 100. Electrical conductors 118 such as bond wires, ribbons, metal clips, etc. encapsulated in the mold compound 114 connect the leads 116 to terminals 120 of the semiconductor die 110. Depending on die type, the semiconductor die 110 can be glued or soldered to the substrate 104. For example in the case of a vertical transistor die 110, the bottom side 122 of the die 110 can include an output pad soldered to the substrate 104. The output pad provides a point of electrical contact for the output terminal of the transistor included in the die 110 e.g. to the drain terminal of a power MOSFET or collector terminal of an IGBT. If no electrical connection is needed at the die backside 122, the die 110 can be glued to the substrate 104 to provide a thermal connection to the backside 122 of the die 110.

Regardless of the type of semiconductor die 110 included in the molded package 100, the adhesion adapter 102 is configured to adapt the adhesion properties of the mold compound 114 to the adhesion properties of the semiconductor die 110 such that the mold compound 114 more strongly adheres to the adhesion adapter 102 than directly to the semiconductor die 110. As such, the adhesion adapter 102 locally enhances adhesion strength along the interface between the mold compound 114 and the adhesion adapter 102.

The adhesion adapter 102 can be attached to a region of the die 110 or substrate 104 where greater adhesion strength is desired. The adhesion properties adapted by the adhesion adapter 102 can include adhesion mechanisms such as mechanical adhesion, chemical adhesion, dispersive adhesion, electrostatic adhesion and diffusive adhesion, surface energy, adhesion strength and other forces that contribute to the magnitude of adhesion between the surfaces (e.g. stringing, microstructures, hysteresis, wettability and adsorption, and lateral adhesion). The adhesion adapter 102 also can have a surface feature which strengthens the adhesion between the adhesion adapter 102 and the mold compound 114. For example, grooves, single or multiple holes, notches, etc. can be formed in the surface of the adhesion adapter 102. Additional surface feature embodiments are described in more detail later herein. In general, a layer of material can be applied to the surface of the adhesion adapter 102 or the surface can be treated to strengthen the adhesion between the adhesion adapter 102 and the mold compound 114.

FIG. 2 illustrates a sectional view of another embodiment of a molded semiconductor package 200 having an adhesion adapter 102. The embodiment shown in FIG. 2 is similar to the embodiment shown in FIG. 1. Different however, the adhesion adapter 102 is attached to the second main surface 108 of the substrate 104 e.g. by an adhesive. In one embodiment, the substrate 104 is a metal lead frame and the adhesion adapter 102 comprises the same lead frame material as the substrate 104. Lead frames tend to be relatively thin and therefore are subject to micro-bending. Attaching the adhesion adapter 102 to a lead frame substrate 104 effectively increases the thickness of the lead frame substrate 104, reducing the likelihood of micro-bending.

Because the adhesion adapter 102 is a discrete component attached to the substrate 104, the substrate 104 need not be modified to locally strengthen adhesion with the molding compound 114. This way, the substrate 104 can be manufactured using standard technologies/processes. The discrete adhesion adapter 102 adapts the adhesion properties of the mold compound 114 to the adhesion properties of the substrate 104 such that the mold compound 114 more strongly adheres to the adhesion adapter 102 than directly to the substrate 104. The local properties of the attached adhesion adapter 102 can be optimized to strengthen adhesion with the mold compound 114, without necessarily having to modify the substrate design. As such, different properties of the substrate 104 such as die or wire bond capability can be ignored since adhesion to the molding compound 114 is locally strengthened by the adhesion adapter 102. Attachment of the adhesion adapter 102 to the substrate 104 results in a topographical change of the substrate 104, which could have positive effects such as creating a barrier for unwanted humidity or chemical substances from entering the package 200 due to delamination.

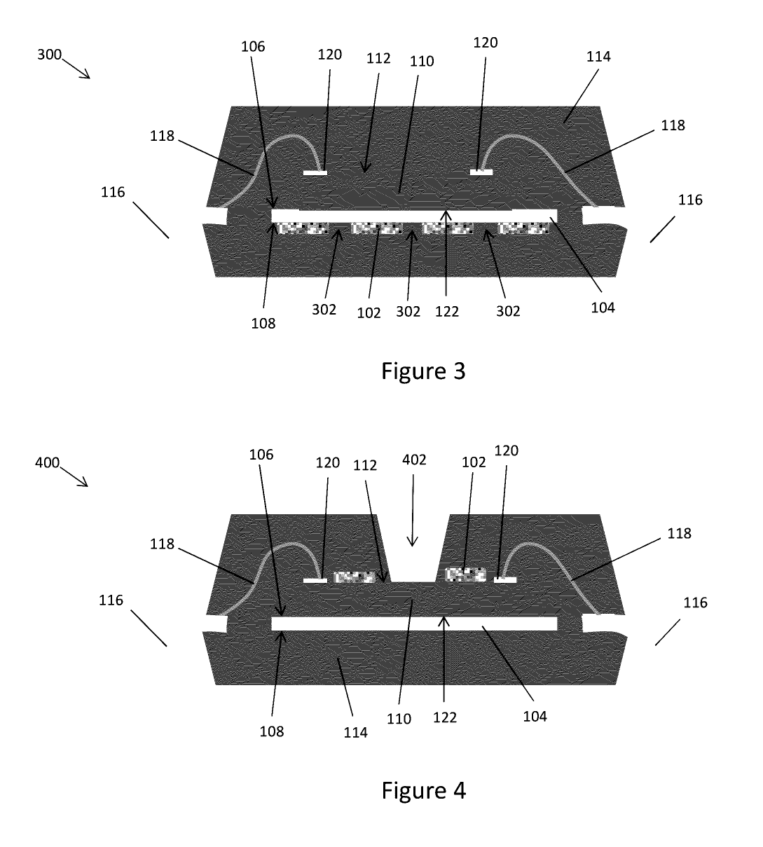

FIG. 3 illustrates a sectional view of yet another embodiment of a molded semiconductor package 300 having an adhesion adapter 102. The embodiment shown in FIG. 3 is similar to the embodiment shown in FIG. 2. Different however, the adhesion adapter 102 has a plurality of openings 302 filled with the mold compound 114. The openings 302 can be formed before or after attachment of the adhesion adapter 102 to the second main surface 108 of the substrate 104.

FIG. 4 illustrates a sectional view of still another embodiment of a molded semiconductor package 400 having an adhesion adapter 102. The embodiment shown in FIG. 4 is similar to the embodiment shown in FIG. 1. Different however, part of the surface 112 of the semiconductor die 110 facing away from the substrate 104 is uncovered by the mold compound 114. For example, the die 110 can be a sensor die and the part of the surface 112 of the die 110 uncovered by the mold compound 114 can include a transducer. An unobstructed passage 402 is provided to the transducer by ensuring the mold compound 114 does not cover this part of the die surface 112. The adhesion adapter 102 can surround the part of the die surface 112 uncovered by the mold compound 114, encircling the transducer. The mold compound 114 is more likely to delaminate from the semiconductor die 110 along the interface between the mold compound 114 and the die 110 in the region of the open passage 402. The adhesion adapter 102 is configured to adapt the adhesion properties of the mold compound 114 to the adhesion properties of the semiconductor die 110 in the region around the open passage 402, such that the mold compound 114 more strongly adheres to the adhesion adapter 102 than directly to the die 110 in this local region of increased delamination risk.

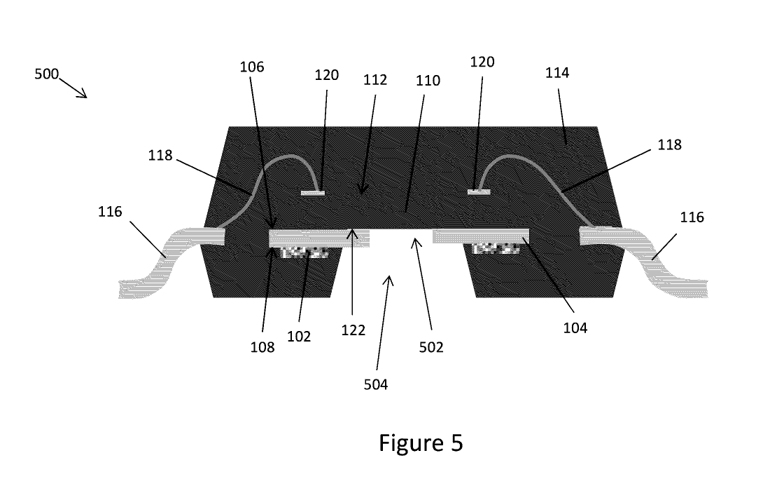

FIG. 5 illustrates a sectional view of another embodiment of a molded semiconductor package 400 having an adhesion adapter 102. The embodiment shown in FIG. 5 is similar to the embodiment shown in FIG. 4. Different however, part of the second surface 108 of the substrate 104 is uncovered by the mold compound 114 and the adhesion adapter 102 is attached to the second surface 108 of the substrate 104. For example, the semiconductor die 110 can be a pressure sensor die having a first side 112 with a pressure sensor port, a second side 112 opposite the first side 122, and electrical contacts 120. The first side 122 of the pressure sensor die 110 faces the first main surface 106 of the substrate 104. The part of the second surface 108 of the substrate 104 uncovered by the mold compound 114 has an opening 502 aligned with the pressure sensor port, providing an open passage 504 through the mold compound 114 and substrate 104 to the pressure sensor port of the die 110. The adhesion adapter 102 surrounds the opening 502 in the substrate 104. For example, the adhesion adapter 102 can be shaped like a flat ring, encircling the pressure sensor port of the die 110. The mold compound 114 is more likely to delaminate from the semiconductor die 110 along the interface between the mold compound 114 and the second surface 108 of the substrate 104 in the region of the open passage 504. The adhesion adapter 102 is configured to adapt the adhesion properties of the mold compound 114 to the adhesion properties of the substrate 104 in the region around the open passage 504, such that the mold compound 114 more strongly adheres to the adhesion adapter 102 than directly to the substrate 104 in this local region of increased delamination risk.

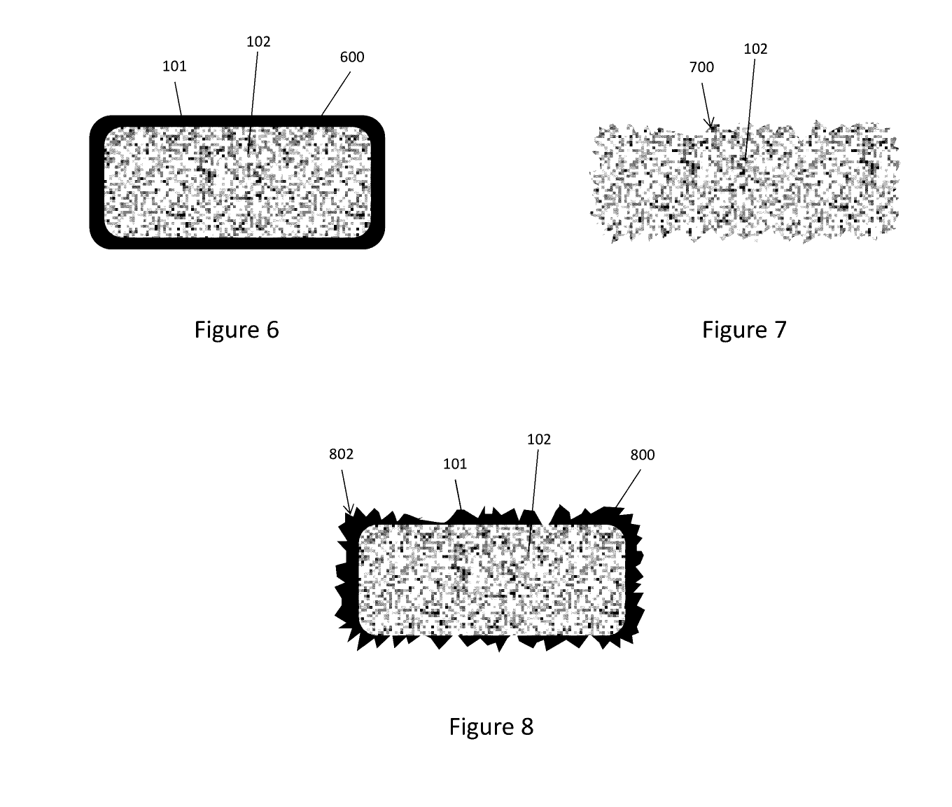

FIGS. 6 through 8 illustrate different surface feature embodiments for the adhesion adapter 102. In each case, the surface feature can be provided on one, some, or all sides of the adhesion adapter 102. For example, the surface feature can be provided on each side of the adhesion adapter 102 covered by the mold compound 114. The surface feature also can be provided on the side of the adhesion adapter 102 which is attached to the substrate 104 or die 110. In general, at least one side of the adhesion adapter 102 can have the surface feature.

In FIG. 6, the surface feature comprises a coating 600 of adhesion promoting material applied to the surface 101 of the adhesion adapter 102. The coating 600 can be applied before or after the adhesion adapter 102 is attached to the substrate 104 or die 110. In one embodiment, the coating 600 is a stable oxide layer deposited on the surface 101 of the adhesion adapter 102. The stable oxide layer 600 creates an enhanced chemical connection with the mold compound 114. The stable oxide layer 600 can be deposited by electrochemical, chemical, plasma, CVD (chemical vapor deposition), PVD (physical vapor deposition), etc. Possible elements which can be used to form the stable oxide layer 600 include e.g. Zn, Al, Cr, Zr, Sn, Si, Ti, etc. In general, elements with a negative potential can be used.

In FIG. 7, the surface feature comprises a roughened surface 700 of the adhesion adapter 102. The original surface 101 of the adhesion adapter 102 can be roughened by depositing, etching, or plating of metal (e.g. Cu, Ni) in the case of a metal adhesion adapter 102, for generating a defined and reproducible micro roughness/topography and morphology 700. Additional sealing of the roughened surface 700 can be provided for stable oxide layer generation. In the case of a plastic adhesion adapter 102, the original surface 101 can be roughened by directing laser or ultrasonic energy at the surface 101 of the plastic adhesion adapter 102.

In FIG. 8, the surface feature comprises a layer 800 applied to the adhesion adapter 102, the layer 800 having a roughened surface 802. For example in the case of a metal adhesion adapter 102, dendrites 800 having a defined nano-roughness and density 802 can be deposited on the original surface 101 of the metal adhesion adapter 102 to provide for stronger chemical and mechanical anchorage to the mold compound 114. Elements such as Zn, Cr, Mo, V, Cu, etc. can be deposited to form a dendritic layer 800 on the original surface 101 of the metal adhesion adapter 102.

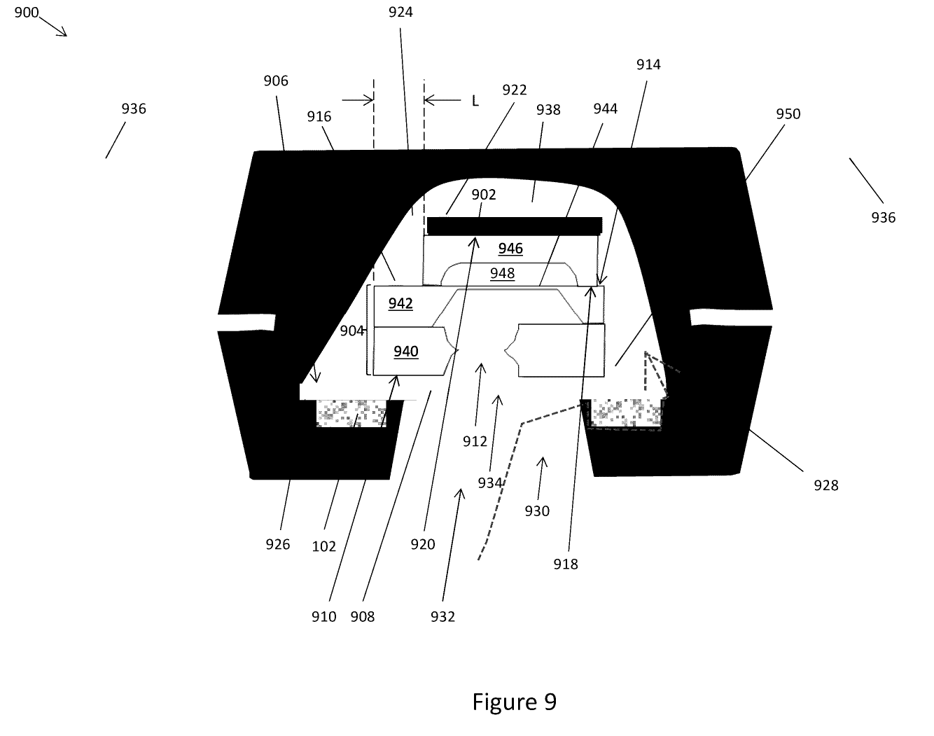

FIG. 9 illustrates a sectional view of an embodiment of a molded pressure sensor package 900 having an adhesion adapter 102. The molded pressure sensor package 900 includes a logic die 902 stacked on a pressure sensor 904. The pressure sensor 904 is attached to a first main surface 906 of a substrate 908 such as a lead frame. The pressure sensor 904 has a first side 910 with a pressure sensor port 912, a second side 914 opposite the first side 910, and electrical contacts 916. The logic die 902 has a first side 918 attached to the second side 914 of the pressure sensor 904 e.g. by an adhesive, solder or other standard die attach material. The second side 920 of the logic die 902 opposite the first side 918 has electrical contacts 922 for the logic die 902. The logic die 902 is laterally offset (L) from the electrical contacts 916 of the pressure sensor 904 so as not to interfere with electrical connections to the pressure sensor 904. In one embodiment, the logic die 902 is an ASIC (applicant-specific integrated circuit) designed to process signals from the pressure sensor 904. This can include signal conditioning, amplification, digitizing, transmitting, receiving, etc. Electrical conductors 924 connect the electrical contacts 916 of the pressure sensor 904 to the electrical contacts 922 of the logic die 902. In FIG. 1, the electrical conductors 924 are shown as wire bonds. However, other types of electrical conductors can be used such as ribbons, metal clips, etc. The adhesion adapter 102 is attached to the second main surface 926 of the substrate 908 i.e. the surface facing away from the logic die/pressure sensor stack 902/904.

Mold compound 928 encapsulates the pressure sensor 904, the logic die 902, the electrical conductors 924, the adhesion adapter 102, and part of the substrate 908. The mold compound 928 has an opening 930 which defines an open passage 932 to the pressure sensor port 912 of the pressure sensor 904. The part of the second surface 926 of the substrate 908 uncovered by the mold compound 928 has an opening 934 aligned with the pressure sensor port 912. External electrical contacts 936 provide points of electrical connection to the pressure sensor 904 and logic die 902 encapsulated in the mold compound 928. The logic die 902, the pressure sensor 904 and part of the electrical conductors 924 can be covered by a silicone gel 938. The silicone gel 938 is interposed between the mold compound 928 and both the logic die 902 and the pressure sensor 904 to decouple the logic die 902 and pressure sensor 904 from mechanical stress generated by the mold compound 928. Any standard silicone gel 938 can be used.

According to the embodiment shown in FIG. 9, the pressure sensor 904 includes a first glass substrate 940 comprising an opening forming the pressure sensor port 912, a silicon die 942 stacked on the first glass substrate 940 and comprising a piezo-active suspended membrane 944, and a second glass substrate 946 stacked on the silicon die 942 and comprising a cavity 948. Signals provided by the silicon die 942 correspond to the amount of movement or displacement of the piezo-active suspended membrane 944 in response to the amount of air flow impinging on the membrane 944. To this end, the opening 912 in the first glass substrate 940 is aligned with the open passage 932 through the mold compound 928 and substrate 908 and with the membrane 944 at one side of the membrane 944 to permit air flowing into the open passage 932 to impinge upon the membrane 944. The cavity 948 in the second glass substrate 946 is aligned with the membrane 944 at an opposite side of the membrane 944 as the opening 912 in the first glass substrate 940 to permit movement of the membrane 944 in response to the air flow.

According to another embodiment of the pressure sensor, one or both of the glass substrates 940, 946 are omitted and the pressure sensor 904 comprises at least the silicon die 942 with the piezo-active suspended membrane 944 over a recessed region of the silicon die 902. The recessed region of the silicon die 902 forms the pressure sensor port according to this embodiment, and is aligned with the open passage 932 though the mold compound 928 and substrate 908 to permit incoming air flow to impinge upon the membrane 944 of the silicon die 942.

In general, any standard pressure sensor 904 can be used. The pressure sensor 904 can include active device areas including transistors e.g. for sensing acceleration. The first side 910 of the pressure sensor 904 can be attached by solder, adhesive or other standard die attach material 950 to the substrate 908 which can be a die paddle (also commonly referred to as die pad) of a lead frame. The substrate 908 is partly encapsulated by the mold compound 928 so that the opening 934 in the substrate 908 aligned with the pressure sensor port 912 is uncovered by the mold compound 928 and permits incoming air flow to impinge upon the membrane 944 of the pressure sensor 904.

In the case of a lead frame die paddle as the substrate 908 to which the first side 910 of the pressure sensor 904 is attached, the external electrical contacts 936 of the pressure sensor package 900 can be leads of the lead frame. The leads 936 are embedded in the mold compound 928 at a first end and protrude out of the mold compound 928 at a second end. The leads 936 can be bent so that the second end of the leads 936 form external electrical contacts at the side of the pressure sensor package 900 opposite the pressure sensor port 912. Alternatively, the leads 936 can be bent in the other direction so that the second end of the leads 936 form external electrical contacts at the side of the pressure sensor package 900 with the pressure sensor port 912.

The mold compound 9128 is more likely to delaminate from the second surface 926 of the substrate 908 along the interface between the mold compound 928 and the substrate 908 in the region of the open passage 932, as indicated by the dashed line in FIG. 9. The adhesion adapter 102 is configured to adapt the adhesion properties of the mold compound 928 to the adhesion properties of the substrate 908 in the region around the open passage 932, such that the mold compound 928 more strongly adheres to the adhesion adapter 102 than directly to the substrate 908 in this local region of increased delamination risk. In one embodiment, the adhesion adapter 102 surrounds the opening 934 in the substrate 908. For example, the adhesion adapter 102 can be shaped like a flat ring, encircling the open passage 932 through the mold compound 928 and substrate 908. The adhesion adapter 102 also can have a surface feature e.g. of the kind previously described herein, which strengthens the adhesion between the adhesion adapter 102 and the mold compound 928.

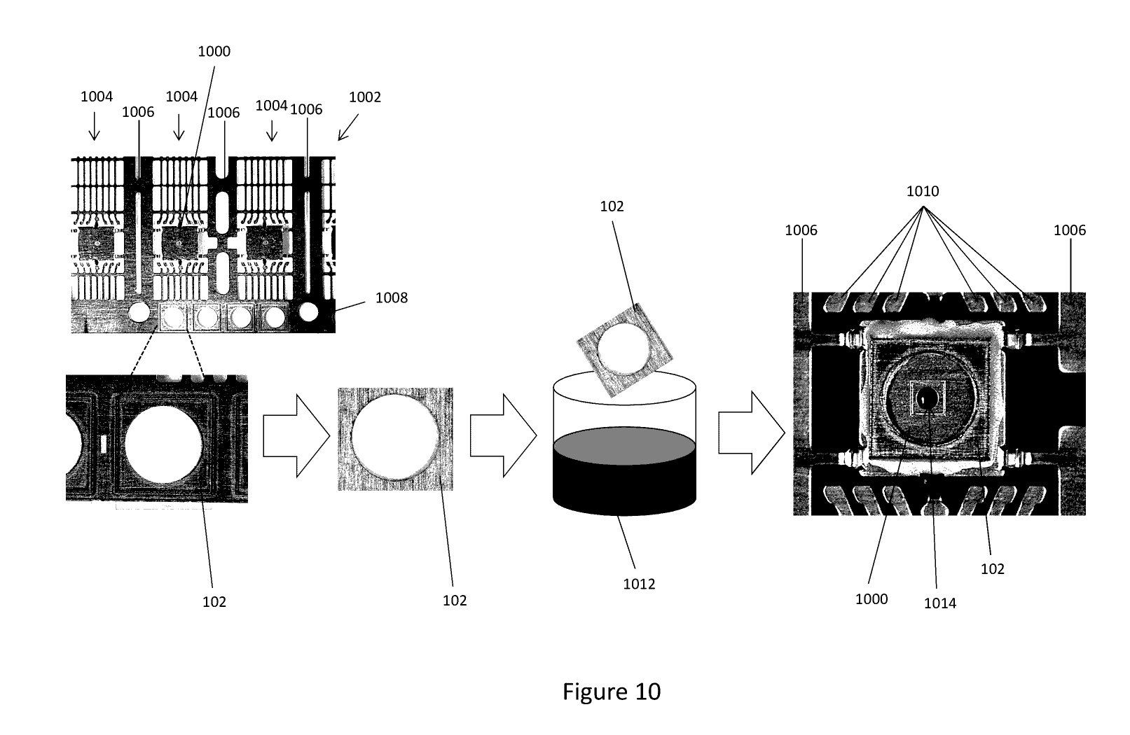

FIG. 10 illustrates an embodiment of a method of attaching the adhesion adapter 102 to a substrate of a molded semiconductor package. According to this embodiment, the substrate is a lead frame (e.g. a die paddle) 1000 and the adhesion adapter 102 is made of the same material as the lead frame 1000. FIG. 10 shows a lead frame strip 1002 which has a plurality of unit lead frames 1004. Each unit lead frame 1004 includes a periphery structure (e.g., a ring-like structure) 1006 connecting adjacent ones of the unit lead frames 1004 to the periphery 1008 of the lead frame strip 1002, a die paddle 1000 inside of the periphery structure 1006, and a plurality of leads 1010 connected to the periphery structure 1006 and extending towards the die paddle 1000. The adhesion adapter 102 is formed in the periphery 1008 of the lead frame strip 1002.

Next, the adhesion adapter 102 is separated from the periphery 1008 of the lead frame strip 1002 e.g. by stamping. The adhesion adapter 102 is then plated e.g. by submersing the adhesion adapter 102 in a plating solution 1012 to form an alloy such as Zn/Cr (e.g. A2) on the surface of the adhesion adapter 102. The alloyed adhesion adapter 102 is then attached to the bottom surface of the lead frame 1000. According to this embodiment, the adhesion adapter 102 is shaped like a flat ring which encircles an opening 1014 in the lead frame 1000 which forms a passage to a pressure sensor port of a die stack to be attached to the opposing surface of the lead frame 1000. Further standard package assembly processes are then performed such as die attach, wire bonding, glob topping, molding, etc. to yield e.g. the molded pressure sensor package 900 shown in FIG. 9.

As previously described herein, an adhesion adapter is provided which adapts the adhesion properties of a mold compound to the adhesion properties of a substrate or semiconductor die of a molded semiconductor package and to which the adhesion adapter is attached, such that the mold compound more strongly adheres to the adhesion adapter than directly to the component to which the adhesion adapter is attached. The adhesion adapter can have a surface feature which strengthens the adhesion between the adhesion adapter and the mold compound also as previously described herein. As such, the adhesion adapter provides macro-locking with the mold compound which is a function of the overall geometry of the adhesion adapter. The surface feature of the adhesion adapter micro-locking with the mold compound which is a function of the type of surface feature used. The adhesion adapter can be attached to the die or substrate. More than one adhesion adapter can be provided so that both the substrate and die have at least one adhesion adapter. The adhesion adapter is not used to provide electrical interconnect to the die.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A molded semiconductor package, comprising:
a substrate having opposing first and second main surfaces;
a semiconductor die attached to the first main surface of the substrate;
an adhesion adapter attached to the second main surface of the substrate or a surface of the semiconductor die facing away from the substrate; and
a mold compound encapsulating the semiconductor die, the adhesion adapter and at least part of the substrate,
wherein the adhesion adapter is configured to adapt adhesion properties of the mold compound to adhesion properties of the substrate or semiconductor die to which the adhesion adapter is attached, such that the mold compound more strongly adheres to the adhesion adapter than directly to the substrate or semiconductor die to which the adhesion adapter is attached,
wherein the adhesion adapter has a surface feature which strengthens the adhesion between the adhesion adapter and the mold compound.

2. The molded semiconductor package of claim 1, wherein the adhesion adapter is attached to the second main surface of the substrate by an adhesive.

3. The molded semiconductor package of claim 1, wherein:
the substrate is a metal lead frame; and
the adhesion adapter comprises the same material as the metal lead frame and is attached to the second main surface of the metal lead frame.

4. The molded semiconductor package of claim 1, wherein:
part of the second surface of the substrate is uncovered by the mold compound; and
the adhesion adapter is attached to the second main surface of the substrate.

5. The molded semiconductor package of claim 4, wherein the adhesion adapter surrounds the part of the second surface uncovered by the mold compound.

6. The molded semiconductor package of claim 5, wherein:
the semiconductor die is a pressure sensor die comprising a first side with a pressure sensor port, a second side opposite the first side, and electrical contacts, the first side of the pressure sensor die facing the first main surface of the substrate;
the part of the second surface of the substrate uncovered by the mold compound has an opening aligned with the pressure sensor port; and
the adhesion adapter surrounds the opening in the substrate.

7. The molded semiconductor package of claim 1, wherein the surface feature is provided on all sides of the adhesion adapter.

8. The molded semiconductor package of claim 1, wherein the surface feature comprises a coating of adhesion promoting material.

9. The molded semiconductor package of claim 1, wherein the surface feature comprises a roughened surface of the adhesion adapter.

10. The molded semiconductor package of claim 1, wherein the surface feature comprises a layer applied to the adhesion adapter, the layer having a roughened surface.

11. The molded semiconductor package of claim 1, wherein the adhesion adapter has a plurality of openings filled with the mold compound.

12. A pressure sensor package, comprising:
a substrate having opposing first and second main surfaces;
a pressure sensor comprising a first side with a pressure sensor port facing the first main surface of the substrate, a second side opposite the first side, and electrical contacts;
a logic die stacked on the pressure sensor and comprising a first side attached to the second side of the pressure sensor and a second side opposite the first side with electrical contacts, the logic die laterally offset from the electrical contacts of the pressure sensor and operable to process signals from the pressure sensor; and
an adhesion adapter attached to the second main surface of the substrate;
a mold compound encapsulating the pressure sensor, the logic die and the adhesion adapter, the mold compound having an opening defining an open passage to the pressure sensor port,
wherein the adhesion adapter is configured to adapt adhesion properties of the mold compound to adhesion properties of the substrate such that the mold compound more strongly adheres to the adhesion adapter than directly to the substrate,
wherein the adhesion adapter has a surface feature which strengthens the adhesion between the adhesion adapter and the mold compound.

13. A method of manufacturing a molded semiconductor package, the method comprising:
providing a substrate having opposing first and second main surfaces;
attaching a semiconductor die to the first main surface of the substrate;
attaching an adhesion adapter to the second main surface of the substrate or a surface of the semiconductor die facing away from the substrate;
encapsulating the semiconductor die, the adhesion adapter and at least part of the substrate in a mold compound, wherein the adhesion adapter is configured to adapt adhesion properties of the mold compound to adhesion properties of the substrate or semiconductor die to which the adhesion adapter is attached, such that the mold compound more strongly adheres to the adhesion adapter than directly to the substrate or semiconductor die to which the adhesion adapter is attached; and
providing the adhesion adapter with a surface feature which strengthens the adhesion between the adhesion adapter and the mold compound.

14. The method of claim 13, wherein providing the adhesion adapter with the surface feature comprises coating the adhesion adapter with an adhesion promoting material.

15. The method of claim 13, wherein providing the adhesion adapter with the surface feature comprises roughening a surface of the adhesion adapter.

16. The method of claim 15, wherein the adhesion adapter comprises metal and wherein the surface of the metal adhesion adapter is roughened by plating the surface of the metal adhesion adapter.

17. The method of claim 15, wherein the adhesion adapter comprises plastic and wherein the surface of the plastic adhesion adapter is roughened by etching the surface of the plastic adhesion adapter.

18. The method of claim 13, wherein providing the adhesion adapter with the surface feature comprises applying a layer having a roughened surface to the adhesion adapter.

19. The method of claim 13, further comprising:
forming a plurality of openings in the adhesion adapter; and
filling the openings with the mold compound.

20. The method of claim 13, wherein:
the substrate comprises a lead frame separated from a lead frame strip; and
attaching the adhesion adapter to the second main surface of the substrate comprises separating the adhesion adapter from a periphery of the lead frame strip and attaching the adhesion adapter to the second main surface of the lead frame.

21. The method of claim 20, wherein part of the second surface of the lead frame is uncovered by the mold compound and wherein the adhesion adapter surrounds the part of the second surface of the lead frame uncovered by the mold compound.
